(19) United States
(12) Patent Application Publication
(10) Pub. No.: US 2006/0001149 A1
(43) Pub. Date: Jan. 5, 2006

(54) Packaged substrate having variable width conductors and a variably spaced reference plane

(76) Inventor: Victor Prokofiev, Phoenix, AZ (US)

Correspondence Address: Stephen M. De Klerk;BLAKELY, SOKOLOFF, TAYLOR & ZAFMAN LLP, Seventh Floor, 12400 Wilshire Boulevard, Los Angeles, CA, 90025, US

(21) Appl. No.: 10/883,049

(22) Filed: Jun. 30, 2004

(51) Int. Cl. H01L 23/48

(52) U.S. Cl. 257/692; 257/690; 257/773

(57) ABSTRACT

A package substrate for a microelectronic die is described. The package substrate has first terminals in a small area and second terminals in a larger area with conductors connecting the first and second terminals. The conductors are fairly narrow near the first terminals so that they can fit next to one another near the first terminals and before fanning out to the second terminals. The reference plane next to the conductors forms a step so that a first surface of the reference plane is closer to the conductors where they are narrow, and a second portion of the reference plane surrounding the first portion is further from the conductors where they are wider. The capacitance created between a respective conductor and the reference plane remains relatively constant per unit length because the reference plane is closer to the conductor where the conductor is narrow and further from the conductor where the conductor is wider.

### BACKGROUND OF THE INVENTION

1). Field of the Invention

This invention relates to an electronic component such as a package substrate in a microelectronic assembly and to constructions that reduce impedance of conductors of the electronic component.

2). Discussion of Related Art

Integrated circuits are usually manufactured in and on semiconductor substrates, which are subsequently “diced” or “singulated” into individual dies. Each die is then mounted to a package substrate for providing electric communication, power, and ground to the die and for providing structural rigidity to the die.

A package substrate typically has a plurality of traces or other conductors that connect first terminals in a first area to second terminals in a second area. Signals are transmitted through these conductors to or from an integrated circuit in the die. A reference plane is usually provided adjacent to the conductors to create a capacitance that reduces impedance of signals. A capacitance created between the reference plane and a respective conductor is preferably relatively uniform along the length of the conductor.

### BRIEF DESCRIPTION OF THE DRAWINGS

The invention is described by way of examples with reference to the accompanying drawings, wherein:

FIG. 1 is a perspective view illustrating conductive components, only, of a package substrate, according to an embodiment of the invention;

FIG. 2 is a top plan view of a portion of a conductor of the package substrate, illustrating roughness on sides of the conductor;

FIG. 3 is a graph illustrating loss against frequency when using a construction according to the invention and a conventional construction;

FIG. 4 is a cross-sectional side view of a microelectronic assembly including the package substrate of FIG. 1;

FIG. 5 is a cross-sectional side view of a microelectronic assembly having a package substrate according to another embodiment of the invention; and

FIG. 6 is a cross-sectional side view of a microelectronic assembly having a package substrate according to a further embodiment of the invention.

### DETAILED DESCRIPTION OF THE INVENTION

A package substrate for a microelectronic die is described. The package substrate has first terminals in a small area and second terminals in a larger area with conductors connecting the first and second terminals. The conductors are fairly narrow near the first terminals so that they can fit next to one another near the first terminals and before fanning out to the second terminals. A reference plane next to the conductors forms a step so that a first surface of the reference plane is closer to the conductors where they are narrow, and a second portion of the reference plane surrounding the first portion is further from the conductors where they are wider. The capacitance created between a respective conductor and the reference plane remains relatively constant per unit length because the reference plane is closer to the conductor where the conductor is narrow and further from the conductor where the conductor is wider.

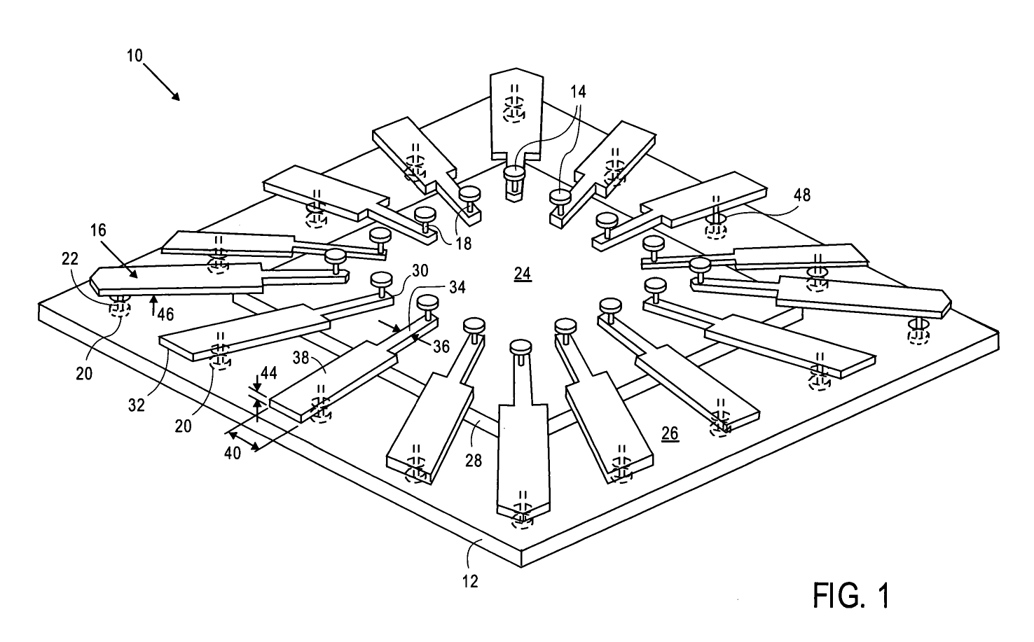

FIG. 1 of the accompanying drawings illustrates conductive metal components, only, of an electronic component in the form of a package substrate 10, according to an embodiment of the invention. The components illustrated in FIG. 1 include a reference plane 12, a first set of terminals 14, conductors 16, a first set of vias 18, a second set of terminals 20, and a second set of vias 22.

The reference plane 12 has first and second upper surfaces 24 and 26. The surfaces 24 and 26 are substantially flat and extend in parallel and horizontal x-y planes. A step 28 is formed between the first and second surfaces 24 and 26 so that the x-y plane of the first surface 24 is higher, in a z-direction, than the second surface 26. When viewed from above, the first surface 24 is rectangular, and the second surface 26 forms a rectangular perimeter surrounding the first surface 24. The first and second surfaces 24 and 26 are at the same voltage potential, e.g., 0V.

Each one of the conductors 16 has an inner end 30 over the first surface 24 and an outer end 32 over the second surface 26. The conductors 16 spread away from one another, or fan out, from an area over the first surface 24 toward an outer periphery of the second surface 26.

Each conductor 16 has an inner first portion 34 having a first width 36 and an outer second portion 38 having a second width 40. The first and second widths 36 and 40 are measured in an x-y plane, and the first width 36 is less than the second width 40. The first width 36 is typically less than 0.5 times the second width 40. The conductors 16 thus have smaller widths where center lines of the conductors 16 are closer to one another, and are wider where more space is provided.

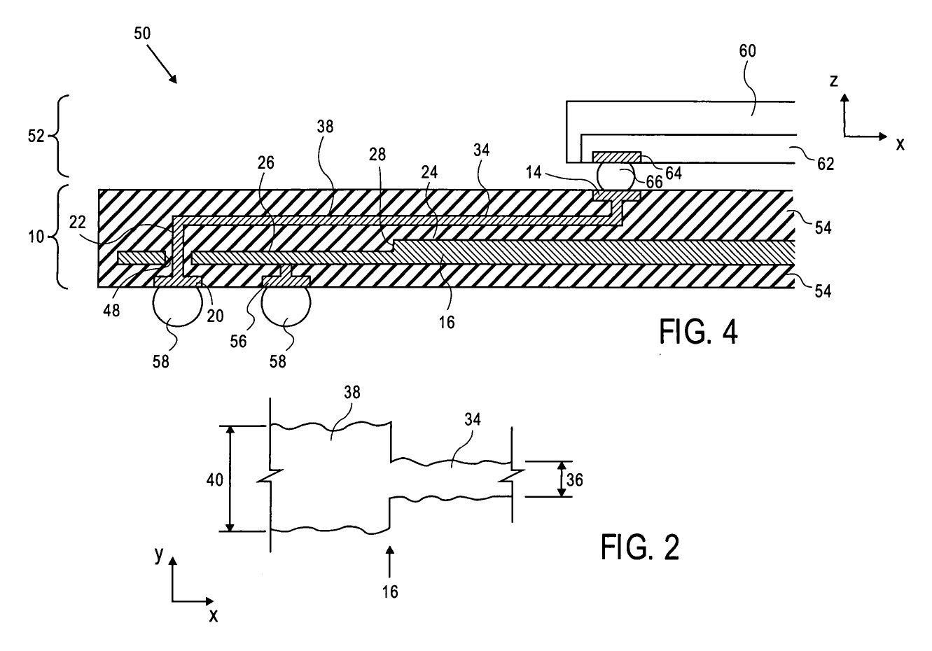

As illustrated in FIG. 2, a conductor 16 has sides with a degree of roughness due to imperfections during manufacture. The roughness is a larger percentage of the first width 36 of the first portion 34 than of the second width 40 of the second portion 38. The length of the first portion 34 is thus preferably as short as possible, while still long enough to provide sufficient space where the conductors 16 are closer to one another.

Referring again to FIG. 1, each conductor 16 has a thickness 44 in the z-direction. The thickness 44 is uniform for the first and second portions 34 and 38. A lower surface 46 of the first and second portions 34 and 38 at the same vertical elevation. The entire lower surface 46 is at the same voltage at a particular moment in time.

What should be noted is that the width of the conductor 16 transitions from the first width 36 to the second width 40 directly above the step 28. The capacitance per unit length is thus approximately the same between the first portion 34 and the reference plane 12 than between the second portion 38 and the reference plane 12. The capacitance per unit length between the first portion 34 and the reference plane 12 is reduced because the first width 36 is less than the second width 40. However, the capacitance between the first portion 34 and the reference plane 12 is increased with respect to the capacitance between the second portion 38 and the reference plane 12, because the lower surface 46 is closer to the first surface 24 than to the second surface 26. The step 28 thus compensates for a tendency for the capacitance per unit length to drop due to the transition from the second width 40 to the first width 36.

The terminals 14 of the first set are located above the first ends of the conductors 16. A respective terminal 14 is connected in a z-direction with the respective inner end 30 through a respective one of the vias 18 of the first set. Similarly, the terminals 20 of the second set are located directly below the outer ends 32 of the conductors 16, and each terminal 20 is connected to a respective outer end 32 through a respective one of the vias 22 of the second set. A plurality of openings 48 are formed vertically through the reference plane 12. Each terminal 20 of the second set is located below the reference plane 12, and the respective vias 22 extend through the respective openings 48 without contacting the reference plane 12.

Signals can transmit between a respective terminal 14 of the first set and a corresponding terminal 20 of the second set through a respective conductor 16. Impedance of a respective conductor 16 is reduced by relatively high capacitance between the reference plane 12 and the respective conductor 16 along the entire length of the conductor 16.

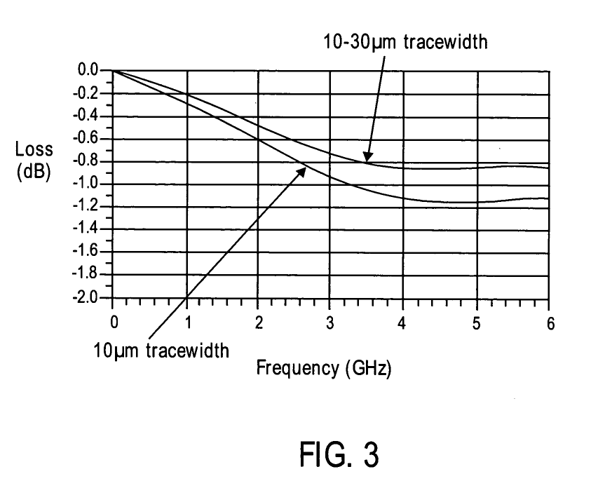

FIG. 3 illustrates the potential reduction in noise due to more uniformity of capacitance along the entire length of a conductor. A 10-micron width conductor (represented by “10 micron trace width”) has about a 1.1 dB noise at 4 GHz, whereas a conductor with a first width of 10 micron and a second width of 30 micron (represented by “10-30 micron trace width”) has noise of 0.85 dB at the same frequency.

FIG. 4 illustrates a microelectronic assembly 50 which includes the package substrate 10 and a microelectronic die 52 mounted to the package substrate 10.

The package substrate 10, in addition to the component hereinbefore described with reference to FIG. 1, further has dielectric material 54, at least one reference plane terminal 56, and a plurality of contact members in the form of solder balls 58. The reference plane 12, conductors 16, and dielectric material 54 are constructed by alternating metal and dielectric layers. The metal layers are patterned and plated to form the reference plane 12 and the conductors 16. Some of the dielectric material spaces the reference plane 12 vertically from the conductors 16. That reference plane 12 may, for example, be manufactured by first forming a single layer having an upper surface in plane with the second surface 26, and then plating or otherwise manufacturing another layer having the first surface 24.

The reference plane terminal 56 is formed alongside and in the same plane as the second terminals 20 and is connected to the reference plane 12. A reference voltage can be provided through the reference plane terminal 56 to the reference plane 12. The solder balls 58 are attached to the terminals 20 and 56. The solder balls 58 can be located on and be soldered to another substrate for providing electric communication with the terminals 20 and providing a reference voltage to the terminal 56.

The microelectronic die 52 has a die substrate 60 and an integrated circuit 62 formed on the substrate 60. The substrate 60 is typically a semiconductor material. The integrated circuit 62 includes a multitude of electronic elements, including transistors, capacitors, diodes, etc., that are manufactured in and on the semiconductor material of the substrate 60. The integrated circuit 62 also includes alternating dielectric and metal lines that form conductors to and from the electronic components. Contact pads 64 are formed on the integrated circuit. Conductive bumps 66 are formed on the contact pads 64. The microelectronic die 52 is placed on the package substrate 10 so that each one of the bumps 66 contacts a respective one of the terminals 14. The bumps 66 are then heated, and allowed to cool so that they are structurally and electrically connected to the terminals 14.

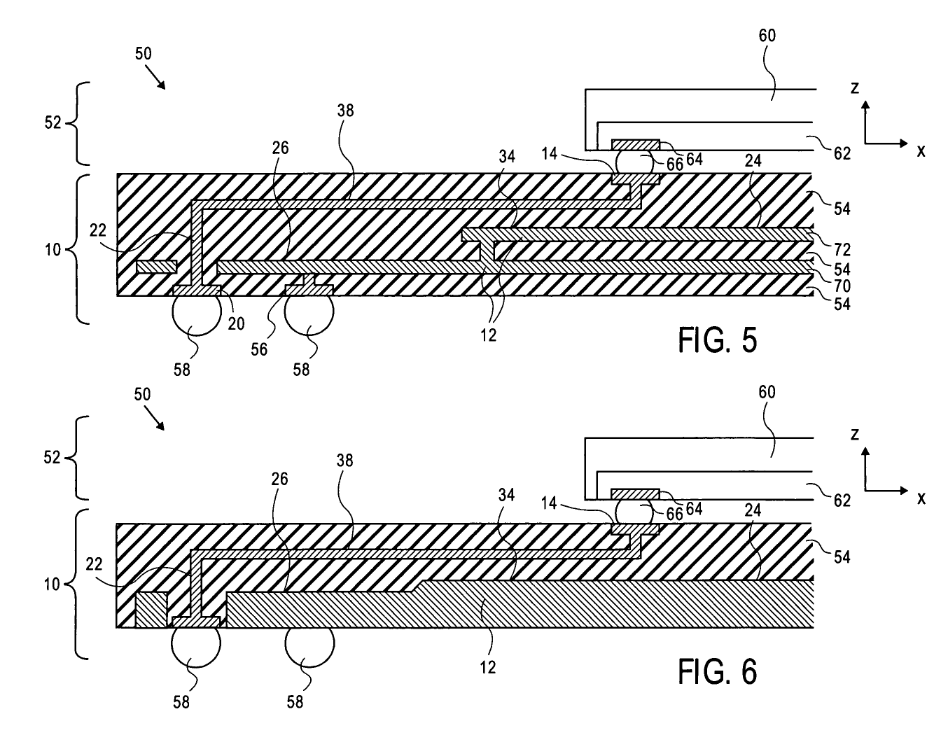

In the embodiment of FIG. 4, the dielectric material 54 is formed below the reference plane 12. It is also continuous from a lower surface thereof to the first surface 24. In the embodiment of FIG. 5, a reference plane 12 is formed by forming two metal planes 70 and 72 with dielectric material 54 between the metal planes 70 and 72. The metal plane 72 forms the first surface 24, and the metal plane 70 forms the second surface 26. The substrate 10 of FIG. 5 is the same as the substrate of FIG. 4 in all other respects.

In FIG. 6 the reference plane 12 is formed without having dielectric material covering a lower surface thereof. One or more solder balls 58 can be attached directly to the reference plane 12.

While certain exemplary embodiments have been described and shown in the accompanying drawings, it is to be understood that such embodiments are merely illustrative and not restrictive of the current invention and that this invention is not restricted to the specific constructions and arrangements shown and described since modifications may occur to those ordinarily skilled in the art. Although specific constructions are, for example, shown and described with reference to a package substrate 10, it will be appreciated that the features may find application in another electronic component such as a microelectronic die, a card, or a mother board. In each embodiment described, a microstrip configuration is used having a single reference plane. Another embodiment may use a stripline configuration having two reference planes on opposing sides of the conductors. One or both of the reference planes may form a step for more uniformed capacitance per unit length.

What is claimed:

1. An electronic component, comprising:
a horizontal substrate having first and second portions and including a dielectric material;
first and second sets of terminals carried by the first and second portions respectively;
a plurality of conductors carried by the substrate, each connecting a respective terminal of the first set with a respective terminal of the second set and having a width, measured horizontally, which is smaller at the first portion than at the second portion; and
a reference plane carried by the substrate and vertically spaced by the dielectric material from the conductors, the reference plane being closer to each conductor at the first portion than at the second portion.

2. The electronic component of claim 1, wherein the first portion is a central portion and the second portion surrounds the first portion, and the conductors fan out from the first portion to the second portion.

3. The electronic component of claim 1, wherein the first and second sets of terminals are on opposing sides of the substrate.

4. The electronic component of claim 1, wherein the width of each conductor at the first portion is at least twice the width of the conductor at the second portion.

5. The electronic component of claim 1, wherein the reference plane has a first surface facing the conductors at the first portion and a second surface facing the conductors at the second portion, the reference plane having a step between the first and second surfaces so that the first surface is closer to the conductors than the second surface.

6. The electronic component of claim 1, further comprising:
a reference plane terminal connected to a reference plane.

7. The electronic component of claim 1, further comprising:
contact members attached to the second terminals and standing above a surface of that substrate.

8. An electronic component, comprising:
a horizontal substrate which, viewed from above, has a first, central portion and a second, outer portion surrounding the first portion;
first and second sets of terminals carried via the first and second portions, respectively, so that the terminals of the second portion are located around the first portion;
a plurality of conductors carried by the substrate, each connecting a respective terminal of the first set with a respective terminal of the second set and spreading away from one another from the first terminals to the second terminals, each conductor having a width, measured horizontally, which is smaller for a first section of the conductor extending over the first portion and for a second section of the conductor extending over the second portion; and
a reference plane carried by the substrate and vertically spaced by the dielectric material from the conductors, the reference plane having a first, central portion at the first portion of the substrate and a second, outer portion at the second portion of the substrate, there being a step from the first to the second portion of the reference plane so that the first portion of the reference plane is closer to the conductors than the second portion of the reference plane.

9. The electronic component of claim 8, wherein the first and second sets of terminals are on opposing sides of the substrate.

10. The electronic component of claim 9, further comprising:
a reference plane terminal connected to the reference plane, the first terminals being on a first side of the substrate, the second terminals being on a second, opposing side of the substrate than the first terminals, and the reference plane terminal being on the second side of the substrate.

11. A microelectronic assembly, comprising:
a horizontal substrate having first and second portions and including a dielectric material;
first and second sets of terminals carried by the first and second portions, respectively, terminals of the first set being spaced from one another by a smaller distance than terminals of the second set;
a plurality of conductors carried by the substrate, each connecting a respective terminal of the first set with a respective terminal of the second set and having a width, measured horizontally, which is smaller at the first portion than at the second portion;
a reference plane carried by the substrate and vertically spaced by the dielectric material from the conductors, the reference plane being closer to each conductor at the first portion than at the second portion;
a microelectronic die having an integrated circuit formed therein; and
a plurality of contacts on the microelectronic die and connected to the integrated circuit, the microelectronic die being mounted to the substrate and each contact being connected to a respective one of the terminals of the first set.

12. The microelectronic assembly of claim 11, wherein the contacts are bumps.

13. The microelectronic assembly of claim 12, wherein the first and second terminals are on opposing sides of the substrate.

14. The microelectronic die of claim 13, further comprising:
a reference plane terminal connected to the reference plane.

15. The microelectronic assembly of claim 11, wherein each conductor has a width at the first portion which is at least twice as wide as a width of the conductor at the second portion.
